(19) United States
(12) Patent Application Publication
(10) Pub. No.: US 2021/0036222 A1
(43) Pub. Date: Feb. 4, 2021

(54) GATE-ALL-AROUND RESISTIVE RANDOM ACCESS MEMORY (RRAM)

(71) Applicant: QUALCOMM Incorporated, San Diego, CA (US)

(72) Inventors: Xia LI, San Diego, CA (US); Bin YANG, San Diego, CA (US); Gengming TAO, San Diego, CA (US)

(21) Appl. No.: 16/524,639

(22) Filed: Jul. 29, 2019

(51) Int. Cl. H01L 45/00; H01L 27/24

(52) U.S. Cl. CPC H01L 45/147; H01L 45/1253; H01L 27/24; H01L 45/16; H01L 45/146

(57) ABSTRACT

Certain aspects of the present disclosure are directed to a resistive random access memory (RRAM). The RRAM generally includes a substrate, an insulator region disposed above the substrate, and a gate region disposed adjacent to at least one lateral surface of the insulator region. The RRAM may also include a first non-insulative region disposed adjacent to a lower surface of the insulator region, and a second non-insulative region disposed adjacent to an upper surface of the insulator region.

### FIELD OF THE DISCLOSURE

The teachings of the present disclosure relate generally to electronic systems, and more particularly, to a memory device.

### BACKGROUND

Electronic devices including processors and memory are used extensively today in almost every electronic application. The processor controls the execution of program instructions, arithmetic functions, and access to memory and peripherals. In the simplest form, the processor executes program instructions by performing one or more arithmetic functions on data stored in memory. There are many different types of memory, which may be implemented using any of various suitable technologies.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

Certain aspects of the present disclosure are directed to a resistive random access memory (RRAM). The RRAM may include a substrate, an insulator region disposed above the substrate, a gate region disposed adjacent to at least one lateral surface of the insulator region, a first non-insulative region disposed adjacent to a lower surface of the insulator region, and a second non-insulative region disposed adjacent to an upper surface of the insulator region.

Certain aspects of the present disclosure are directed to a method for fabricating a RRAM. The method generally includes forming a first non-insulative region above a substrate, forming an insulator region above the substrate, forming a gate region adjacent to at least one lateral surface of the insulator region, and forming a second non-insulative region adjacent to a lower surface of the insulator region, the first non-insulative region being formed adjacent to an upper surface of the insulator region.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is an illustration of an exemplary system-on-chip (SoC) integrated circuit design, in accordance with certain aspects of the present disclosure.

FIG. 2 illustrates a resistive random access memory (RRAM) implemented with a solid electrolyte, in accordance with certain aspects of the present disclosure.

FIG. 3 illustrates an RRAM implemented with a gate oxide, in accordance with certain aspects of the present disclosure.

FIGS. 4A-4F illustrate example operations for fabricating the RRAM of FIG. 2, in accordance with certain aspects of the present disclosure.

FIGS. 5A-5D illustrate example operations for fabricating the RRAM of FIG. 3, in accordance with certain aspects of the present disclosure.

FIG. 6 is a flow diagram illustrating example operations for fabricating an RRAM, in accordance with certain aspects of the present disclosure.

### DETAILED DESCRIPTION

Certain aspects of the present disclosure are generally directed to a resistive random access memory (RRAM) implemented using a gate region disposed all around an insulator. The RRAM described herein has improved linearity as compared to conventional implementations, as explained in more detail below.

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

The various aspects will be described in detail with reference to the accompanying drawings. Wherever possible, the same reference numbers will be used throughout the drawings to refer to the same or like parts. References made to particular examples and implementations are for illustrative purposes, and are not intended to limit the scope of the disclosure or the claims.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., ROM, RAM, flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

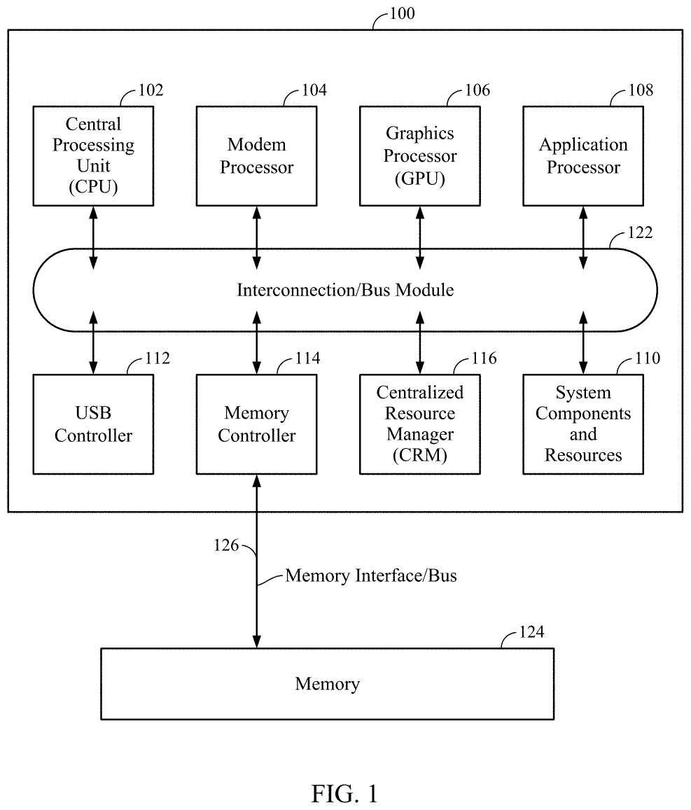

FIG. 1 illustrates example components and interconnections in a system-on-chip (SoC) 100 suitable for implementing various aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture (e.g., CoreConnect, AMBA, etc.). Communications may also be provided by advanced interconnects, such as high performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously.

The memory controller 114 may be a specialized hardware module configured to manage the flow of data to and from a memory 124 via a memory interface/bus 126. In certain aspects, the memory 124 may be a resistive random access memory (RRAM), as described in more detail herein.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the SoC 100.

### EXAMPLE DISCRETE CHARGE LAYER MEMORY DEVICE

Resistive random access memory (RRAM, also known as ReRAM) is a form of nonvolatile storage that operates by changing the resistance of an insulator between source and drain regions of the RRAM. For example, positive voltage pulses may be applied between gate and source regions of the RRAM, each positive voltage pulse increasing the conductance of the dielectric material. Moreover, negative voltage pulses may be applied between gate and source regions of the RRAM, each negative voltage pulse decreasing the conductance of the dielectric material.

The linearity and symmetry associated with the increase and decrease of the conductance is important, especially for neuromorphic computing. Neuromorphic computing generally refers to the use of very-large-scale integration (VLSI) systems containing electronic analog circuits to mimic neuro-biological architectures present in the nervous system. Certain aspects of the present disclosure are directed to a gate-all-around (GAA) implementation of the RRAM with improved linearity as compared to conventional implementations. A GAA RRAM generally refers to a RRAM having a gate region implemented around lateral surfaces of a channel of the RRAM.

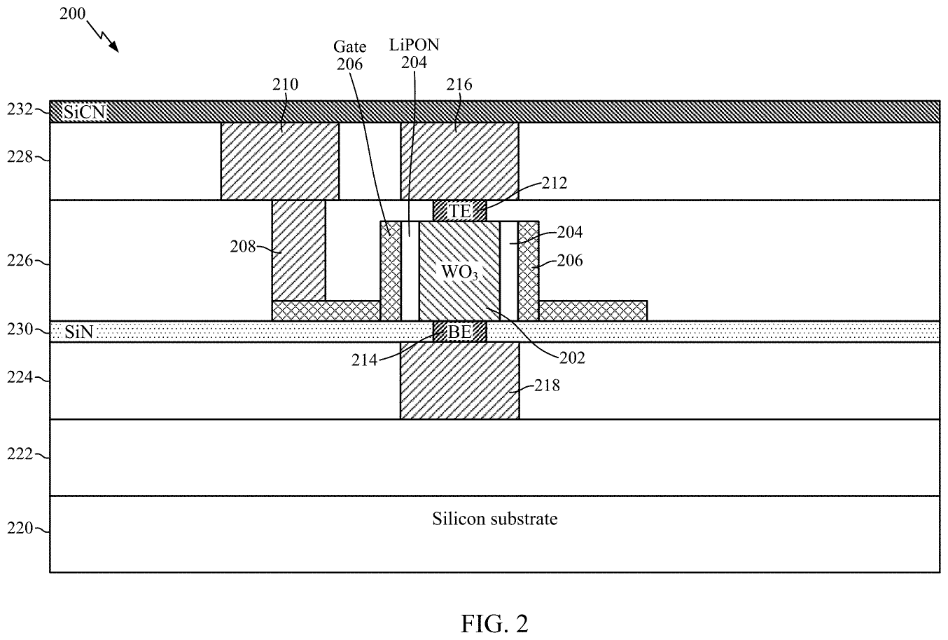

FIG. 2 illustrates an example RRAM 200 implemented with a solid electrolyte 204, in accordance with certain aspects of the present disclosure. The RRAM 200 may include an insulator region 202. For example, the insulator region 202 may be implemented using tungsten trioxide (WO₃).

The RRAM 200 may also include the solid electrolyte 204, which may be implemented adjacent to multiple lateral sides of the insulator region. For instance, the solid electrolyte 204 may be disposed continuously around all lateral surfaces of the insulator region 202. In certain aspects, the solid electrolyte 204 may be implemented via lithium phosphorus oxynitride (LiPON) or delithiated lithium cobaltate (Li₁₋ₓCoO₂). The solid electrolyte 204 intercalates into the insulator region 202, or extracts from the insulator region 202, Li ions (Li+) to adjust the conductance of the insulator region 202. The RRAM 200 may also include a gate region 206, which may be implemented surrounding lateral surfaces of the solid electrolyte 204, as illustrated. A via 208 and a contact region 210 may be implemented to facilitate electrical connection with the gate region 206.

In certain aspects, a top electrode (TE) 212 (e.g., source region, also referred to as a non-insulative region) and a bottom electrode (BE) 214 (e.g., drain region, also referred to as a non-insulative region) may be implemented adjacent to top and bottom sides of the insulator region 202. A non-insulative region generally refers to any region that may be conductive or semiconductive. The BE 214 may be adjacent to a silicon nitride (Si₃N₄) film 230, as illustrated. Contact region 216 and bottom metal region 218 may be implemented to facilitate electrical connection with the TE 212 and the BE 214, respectively. The RRAM 200 may be implemented above a substrate 220 and a dielectric region 222 (e.g., an interlayer dielectric (ILD)). The RRAM 200 may also include dielectric regions 224, 226, 228, as illustrated. In certain aspects, a diffusion barrier layer 232 may be implemented above the RRAM 200, as illustrated.

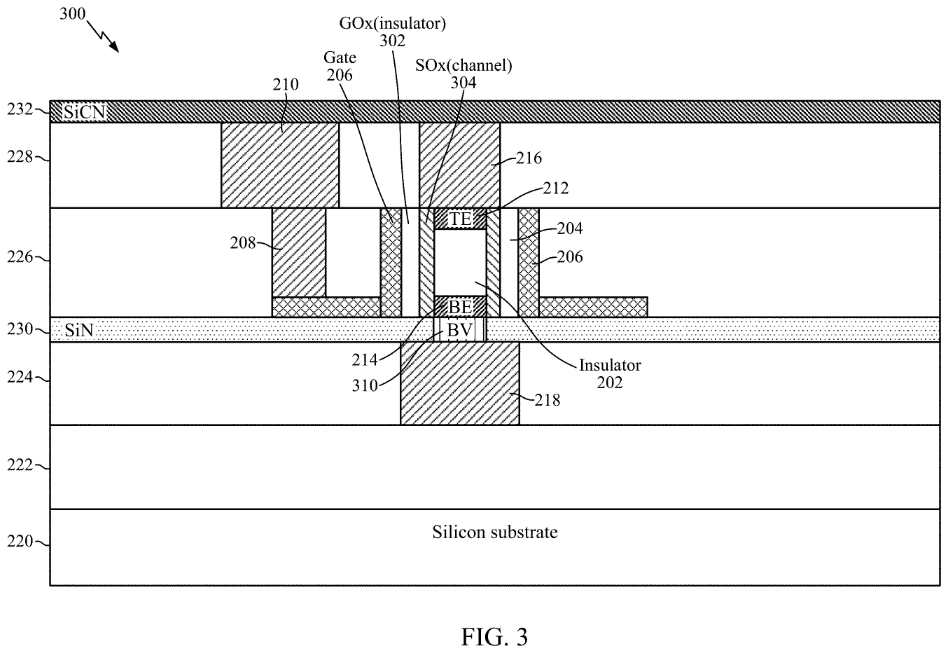

FIG. 3 illustrates an RRAM 300 implemented with a gate oxide 302, in accordance with certain aspects of the present disclosure. As illustrated, the RRAM 300 includes a channel film 304 implemented around lateral surfaces of the insulator region 202, which may be implemented using an oxide material such as strontium titanate (SrTiO₃) or niobium pentoxide (Nb₂O₅). The channel film 304 may comprise an oxovanadium (IV) cation (Vₒ²⁺) oxygen vacancy filament. For example, the channel film 304 may be a Vₒ²⁺ oxygen vacancy filament to intercalate Vₒ²⁺ in or extract out of the insulator region 202 based on modulation of a voltage applied to the gate region. In certain aspects, the insulator region 202 may be implemented using a dielectric oxide, such as tantalum oxide (TaOₓ), hafnium oxide (HfOₓ), tungsten oxide (WOₓ), or titanium oxide (TiOₓ).

In certain aspects, the channel film 304 may be implemented using strontium titanate (SrTiO₃) or niobium pentoxide (Nb₂O₅). The RRAM 300 may also include the gate oxide 302 which may be disposed surrounding lateral surfaces of the channel film 304. A bottom via (BV) 310 may be implemented for electrically connecting the BE 214 with the bottom metal region 218, as illustrated.

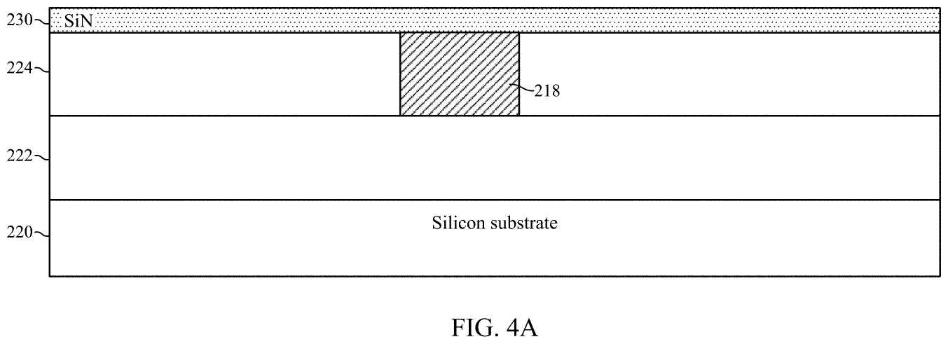

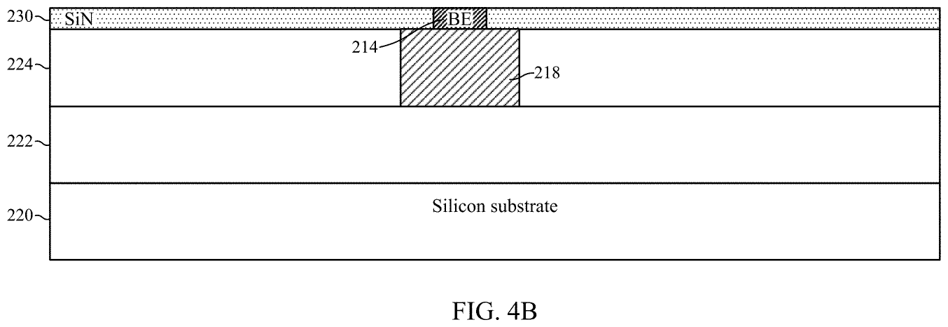

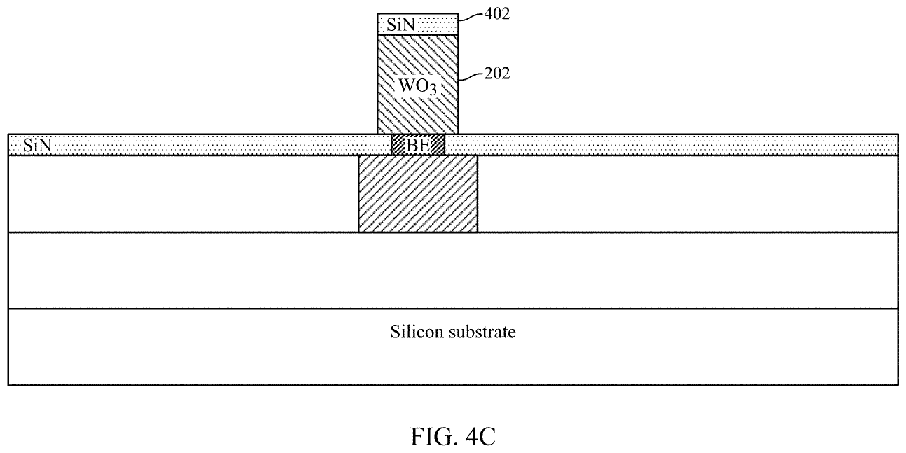

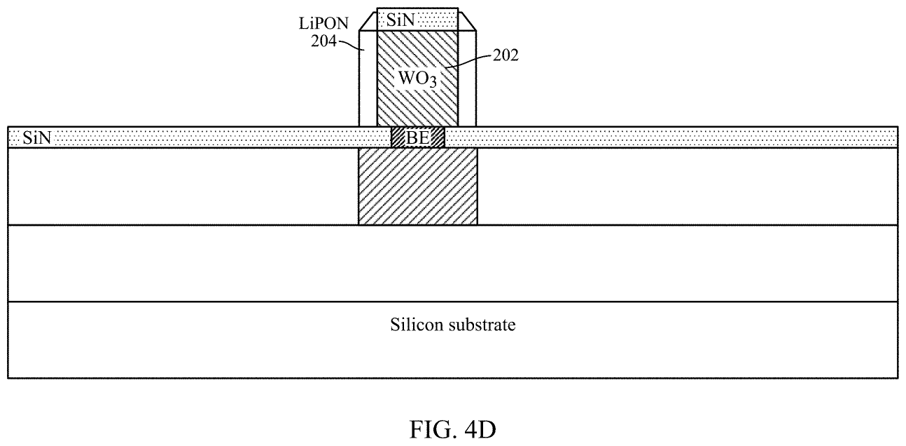

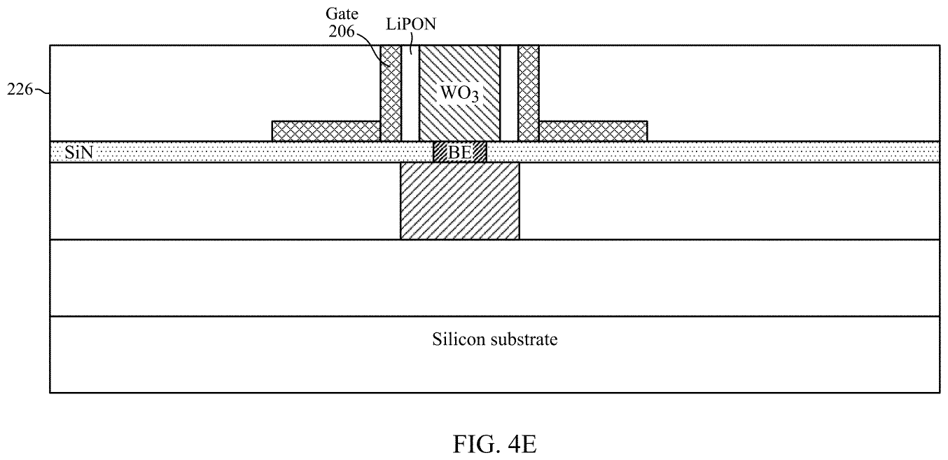

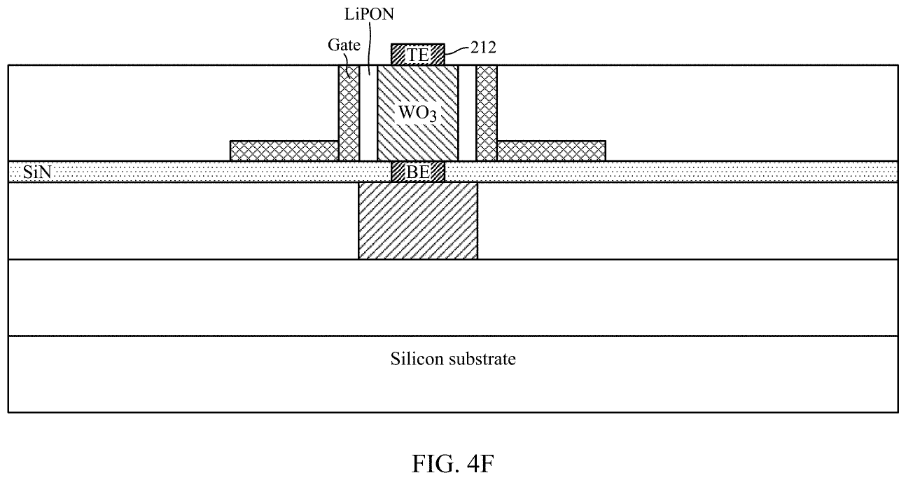

FIGS. 4A-4F illustrate example operations for fabricating the RRAM 200, in accordance with certain aspects of the present disclosure. As illustrated in FIG. 4A, the dielectric regions 222, 224 and the bottom metal region 218 are formed above the substrate 220, followed by deposition of the Si₃N₄ film 230. As illustrated in FIG. 4B, photo and etch patterning of a bottom via may be performed, followed by deposition of bottom electrode film (e.g., tantalum (Ta), tantalum nitride (TaN), titanium (Ti), titanium nitride (TiN), tungsten (W)) and chemical mechanical polishing (CMP) of the RRAM 200, to form the BE 214.

As illustrated in FIG. 4C, an insulator region 202 (e.g., WO₃) may be deposited, followed by deposition of a hardmask film 402 (e.g., Si₃N₄). As illustrated in FIG. 4D, solid electrolyte material may be deposited, followed by an etch-back process, to form the solid electrolyte 204. As illustrated in FIG. 4E, gate film (e.g., titanium nitride (TiN), platinum (Pt), tantalum nitride (TaN), tungsten (W)) may be deposited, followed by photo and etch gate patterning to form the gate region 206. Moreover, oxide film may be deposited, followed by CMP of the RRAM 200, to form the dielectric region 226.

As illustrated in FIG. 4F, TE film (e.g., TaN, Ta, Ti, TiN, W, Pt) may be deposited, followed by photo and etch patterning of the TE 212, to form the TE 212. After the formation of the TE 212, the dielectric region 228 may be formed, followed by CMP of the RRAM 200. Barrier and copper (Cu) seed film deposition, Cu plating, Cu CMP of the RRAM 200, deposition of diffusion barrier Si₃N₄ (e.g., to form diffusion layer 232), and back-end-of-line (BEOL) metallization process may be performed, to form the RRAM 200 illustrated in FIG. 2.

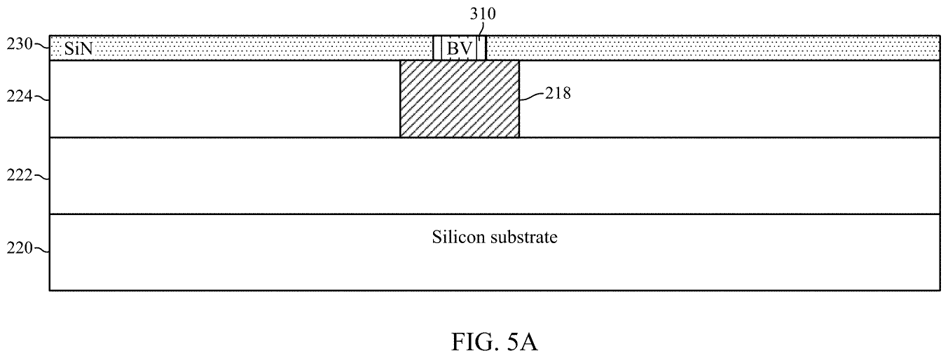

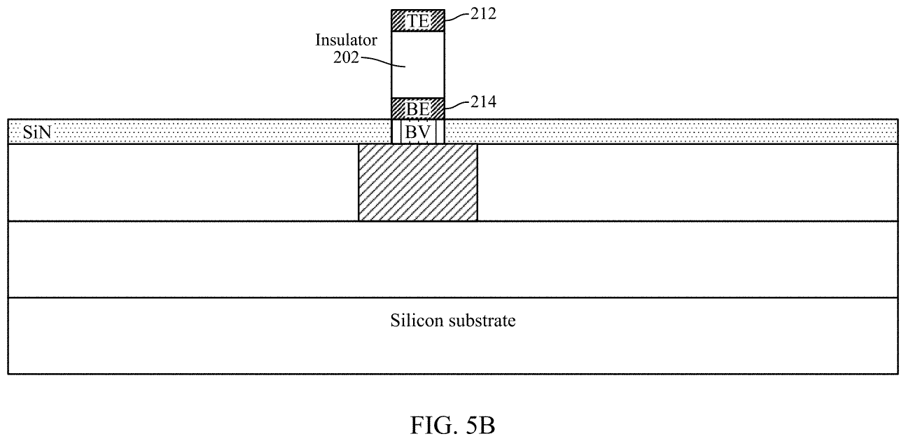

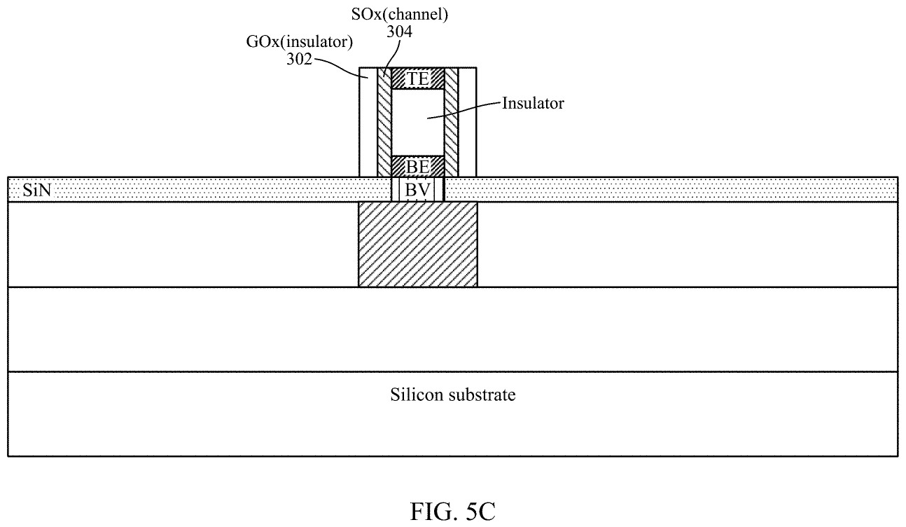

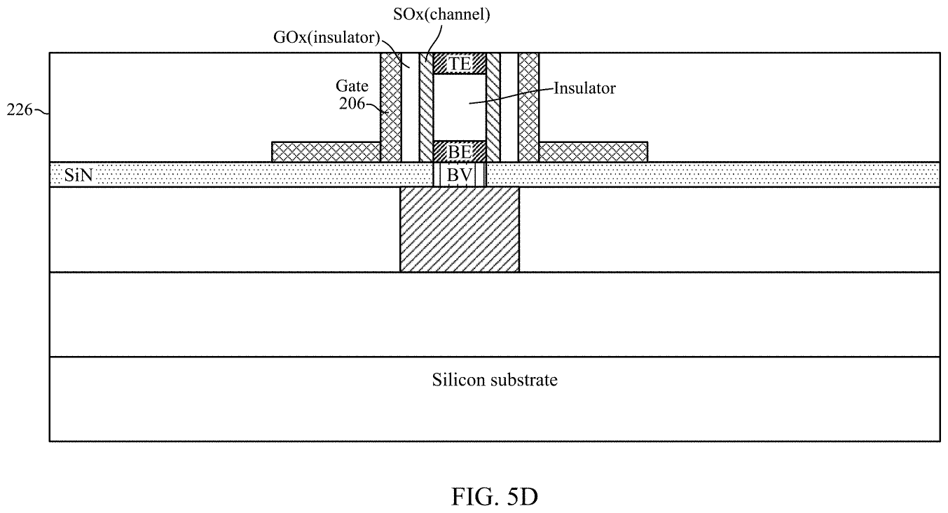

FIGS. 5A-5D illustrate example operations for fabricating the RRAM 300, in accordance with certain aspects of the present disclosure. As illustrated in FIG. 5A, the dielectric regions 222, 224 may be deposited, followed by deposition of the Si₃N₄ film 230. Photo and etch patterning of a via may be performed, followed by deposition of a bottom electrode film (e.g., Ta, TaN, Ti, TiN, W) and CMP of the RRAM 300 to form the BV 310.

As illustrated in FIG. 5B, bottom electrode film, dielectric material, and top electric film may be deposited, followed by photo and etch patterning of the RRAM 200, to form the BE 214, insulator region 202, and TE 212. As illustrated in FIG. 5C, channel film material and gate oxide material may be deposited, followed by an etch-back process, to form the channel film 304 and the gate oxide 302. As illustrated in FIG. 5D, gate film may be deposited, followed by photo and etch patterning of the gate to form the gate region 206. After the formation of the gate region 206, the dielectric regions 226 may be formed, followed by CMP of the RRAM 300. Barrier and copper (Cu) seed film deposition, Cu plating, Cu CMP of the RRAM 300, deposition of diffusion barrier Si₃N₄ (e.g., to form diffusion layer 232), and back end of line (BEOL) metallization process may be performed, to form the RRAM 300, illustrated in FIG. 3.

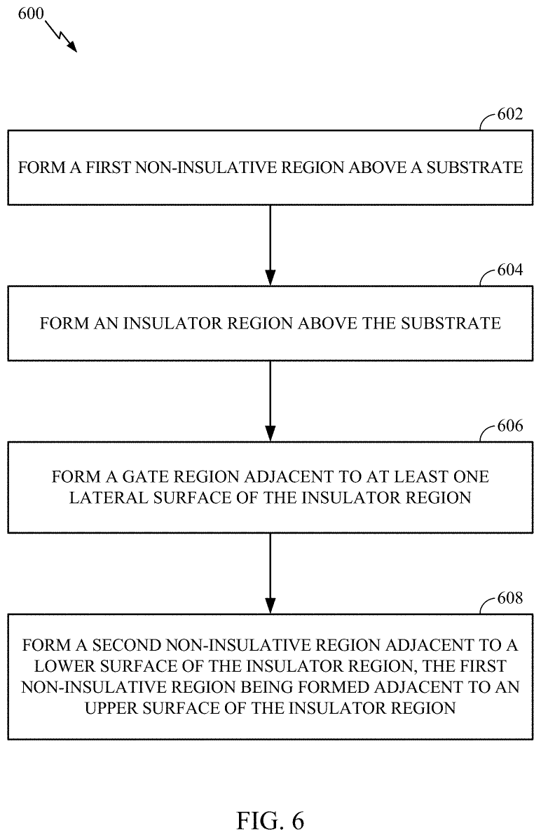

FIG. 6 is a flow diagram illustrating example operations 600 for fabricating a RRAM, in accordance with certain aspects of the present disclosure. The operations 600 may be performed via a semiconductor fabrication chamber.

The operations 600 begin, at block 602, with the semiconductor fabrication chamber forming a first non-insulative region (e.g., drain region) above a substrate (e.g., substrate 220), and at block 604, forming an insulator region (e.g., insulator region 202) above the substrate. At block 606, the semiconductor fabrication chamber may form a gate region (e.g., gate region 206) adjacent to at least one lateral surface of the insulator region. For instance, the gate region may be formed surrounding lateral surfaces of the insulator region. At block 608, the semiconductor fabrication chamber may form a second non-insulative region (e.g., source region) adjacent to a lower surface of the insulator region. In certain aspects, the first non-insulative region is formed adjacent to an upper surface of the insulator region.

In certain aspects, the semiconductor fabrication chamber may also form a solid electrolyte region (e.g., solid electrolyte 204) adjacent to the insulator region before forming the gate region. In this case, the gate region is formed adjacent to the solid electrolyte region.

In certain aspects, the semiconductor fabrication chamber may also form a channel film region (e.g., channel film 304) adjacent to the insulator region before forming the gate region, the gate region being formed adjacent to the channel film. In certain aspects, the semiconductor fabrication chamber may also form a dielectric region (e.g., gate oxide 302) adjacent to the channel film region before forming the gate region, the gate region being formed adjacent to the dielectric region.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein. The algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. A resistive random access memory (RRAM), comprising:
a substrate;
an insulator region disposed above the substrate;
a gate region disposed adjacent to at least one lateral surface of the insulator region;
a first non-insulative region disposed adjacent to a lower surface of the insulator region; and
a second non-insulative region disposed adjacent to an upper surface of the insulator region.

2. The RRAM of claim 1, further comprising a solid electrolyte region disposed between the gate region and the insulator region.

3. The RRAM of claim 2, wherein the solid electrolyte region comprises lithium phosphorus oxynitride (LiPON) or delithiated lithium cobaltate (Li₁₋ₓCoO₂).

4. The RRAM of claim 2, wherein the solid electrolyte region surrounds lateral surfaces of the insulator region.

5. The RRAM of claim 4, wherein the solid electrolyte region is configured to intercalate or extract ions to or from the insulator region based on a voltage applied to the gate region.

6. The RRAM of claim 1, wherein the gate region is disposed around lateral surfaces of the insulator region.

7. The RRAM of claim 1, wherein the insulator region comprises an oxide material.

8. The RRAM of claim 7, wherein the oxide material comprises at least one of tantalum oxide (TaOₓ), hafnium oxide (HfOₓ), tungsten oxide (WOₓ), or titanium oxide (TiOₓ).

9. The RRAM of claim 1, further comprising a channel film region disposed between the gate region and the insulator region.

10. The RRAM of claim 9, wherein the channel film region is configured to intercalate or extract oxovanadium (IV) cation (Vₒ²⁺) oxygen to or from the insulator region based on a voltage applied to the gate region.

11. The RRAM of claim 9, wherein the channel film region comprises an oxide material.

12. The RRAM of claim 11, wherein the oxide material comprises at least one of strontium titanate (SrTiO₃) or niobium pentoxide (Nb₂O₅).

13. The RRAM of claim 9, further comprising a dielectric region disposed between the gate region and the channel film region.

14. The RRAM of claim 13, wherein the first non-insulative region comprises a first electrode and wherein the second non-insulative region comprises a second electrode, the channel film region being disposed around lateral surfaces of the first electrode and the second electrode.

15. The RRAM of claim 1, wherein the first non-insulative region comprises a source region of the RRAM and wherein the second non-insulative region comprises a drain region of the RRAM.

16. A method for fabricating a resistive random access memory (RRAM), comprising:
forming a first non-insulative region above a substrate;
forming an insulator region above the substrate;
forming a gate region adjacent to at least one lateral surface of the insulator region; and
forming a second non-insulative region adjacent to a lower surface of the insulator region, the first non-insulative region being formed adjacent to an upper surface of the insulator region.

17. The method of claim 16, further comprising forming a solid electrolyte region adjacent to the insulator region before forming the gate region, the gate region being formed adjacent to the solid electrolyte region.

18. The method of claim 16, wherein the first non-insulative region comprises a drain region and wherein the second non-insulative region comprises a source region.

19. The method of claim 16, further comprising forming a channel film region adjacent to the insulator region before forming the gate region, the gate region being formed adjacent to the channel film region.

20. The method of claim 19, further comprising forming a dielectric region adjacent to the channel film region before forming the gate region, the gate region being formed adjacent to the dielectric region.
